(19) United States
(12) Patent Application Publication
(10) Pub. No.: US 2002/0149038 A1
(43) Pub. Date: Oct. 17, 2002

(54) Semiconductor device

(76) Inventors: Yoshifumi Yoshida, Chiba-shi (JP); Jun Osanai, Chiba-shi (JP)

Correspondence Address: ADAMS & WILKS, 31st FLOOR, 50 BROADWAY, NEW YORK, NY, 10004, US

(21) Appl. No.: 10/116,641

(22) Filed: Apr. 3, 2002

(30) Foreign Application Priority Data
Apr. 4, 2001 (JP) 2001-106095

(51) Int. Cl. H01L 29/80

(52) U.S. Cl. 257/274

(57) ABSTRACT

There is provided a semiconductor device in which improvement of drive capacity, miniaturization, improvement of reliability of a gate insulating film are achieved. The semiconductor device includes a gate insulating film which is located on a semiconductor substrate and nitrided, a P-type polycrystalline silicon gate electrode located on the gate insulating film, an insulating film located on the gate electrode, low concentration impurity regions each having a low concentration impurity introduced in the vicinity of the surface of the semiconductor substrate in a self alignment manner using the gate electrode as a mask, and high concentration impurity regions which are spaced from the gate electrode and each have a high concentration impurity introduced in the vicinity of the surface of the semiconductor substrate. Such a semiconductor device composes a surface channel P-type transistor and a buried channel N-type transistor.

### BACKGROUND OF THE INVENTION

1. Field of the Invention

The present invention relates to a semiconductor device of a field effect type having a MOS structure. More specifically, the present invention relates to a semiconductor device composing a semiconductor integrated circuit such as a voltage regulator, switching regulator, or a voltage detector, which is used for controlling a power source voltage of a portable device or the like.

2. Description of the Related Art

FIG. 2 is a schematic cross sectional view of a conventional semiconductor device. This is a complementary MOS (hereinafter referred to as a CMOS) structure which is composed of an N-channel MOS transistor (hereinafter referred to as an NMOS) in which the gate electrode formed in a P-type semiconductor substrate is made of an N+-type polycrystalline silicon and a P-channel MOS transistor (hereinafter referred to as a PMOS) in which the gate electrode formed in an N-well region is made of an N+-type polycrystalline silicon.

In the case of a conventional structure in which a channel region which is doped with an impurity having an opposite polarity is interposed between impurity regions such as a source and a drain which have a sufficiently high impurity concentration, electric fields near interfaces between the channel region and the impurity regions are increased by a voltage applied between the source and the drain with reducing the channel region. As a result, the operation of the transistor becomes extremely unstable. There is an LDD (lightly doped drain) structure using spacers as a transistor structure for solving such a problem.

As shown in FIG. 2, this structure is composed of an N-type polycrystalline silicon gate electrode 22, a gate insulating film 21, spacers 23, impurity regions having a low concentration, and impurity regions having a high concentration. The impurity regions having a low concentration provided to be shallower than the impurity regions having a high concentration is called LDDS. When such regions are provided, electric fields near interfaces between the channel region and the impurity regions can be reduced and the operation of the element can be stabilized.

In addition to the LDD structure, an offset LDD structure using a mask has been known. This structure is composed of the N-type polycrystalline silicon gate electrode 22, the gate insulating film 21, the impurity regions having a low concentration, and the impurity regions having a high concentration, as shown in FIG. 2. The structure does not include the spacers 23 used in the LDD structure. Thus, it is different from the case of the LDD structure using the spacers 23, an interval between the impurity regions having a high concentration and the N-type polycrystalline silicon gate electrode can be set to be wide. Therefore, in the case of a drain apply voltage of 7 V, the interval is set to be about 0.5 to 1.0 μm. In the case of 10 V, it is set to be about 0.7 to 2.0 μm. In the case of 36 V, it is set to be about 2.0 to 5.0 μm.

Then, as in the case where a general integral circuit is manufactured, a boron-phosphorus glass layer and a phosphorus glass layer are formed for an interlayer insulating film 10. For example, a low pressure CVD method is preferably used for the formation of the interlayer insulating film 10. After that, holes for electrode formation are formed in the interlayer insulating film and metallic electrodes 11 are formed therein. Thus, a complementary semiconductor device is completed.

With respect to the semiconductor device having the above conventional structure, in the case of an enhancement type NMOS (hereinafter referred to as an E-type NMOS) having a reference threshold voltage of about 0.7 V, the gate electrode is made of polycrystalline silicon having an N+-type as a conductivity type. Thus, from a relationship of work functions between the gate electrode and a semiconductor substrate, the channel is a surface channel formed on the surface of the semiconductor substrate. On the other hand, in the case of an enhancement type PMOS (hereinafter referred to as an E-type PMOS) having a reference threshold voltage of about −0.7 V, from a relationship of work functions between the gate electrode made of an N+-type polycrystalline silicon and an N-well, the channel becomes a buried channel formed somewhat inside the semiconductor substrate rather than the surface of the semiconductor substrate.

In order to realize a low voltage operation, when a threshold voltage is set to be, for example, −0.5 V or more in the buried channel E-type PMOS, a subthreshold characteristic as one index for low voltage operation of the MOS transistor is extremely deteriorated. Thus, a leak current at an off state of the PMOS is increased. As a result, since a consumption current during standby of the semiconductor device is markedly increased, there arises a problem in that an application to portable devices represented by a mobile telephone and a portable terminal which are said to increase demand in recent years and to further expand the market in the future is difficult.

On the other hand, as a technical method of making a low voltage operation and a low consumption current as the above objects compatible, a so-called homopolar gate technique in which a conductivity type of the gate electrode of an NMOS is made to be an N-type and a conductivity type of the gate electrode of a PMOS is made to be a P-type is generally known. In this case, both an E-type NMOS transistor and an E-type PMOS transistor are surface channel MOS transistors. Thus, even when a threshold voltage is reduced, extreme deterioration of a subthreshold coefficient is not actualized and both low voltage operation and a low consumption current are enabled.

However, there are the following problems in cost and characteristics. That is, with respect to a homopolar gate CMOS, the gates in both an NMOS and a PMOS are formed to be different polarities in manufacturing steps. Thus, as compared with a CMOS having a gate electrode made of only an N+-polycrystalline silicon unipole, the number of steps is increased and increases in a manufacturing cost and a manufacturing period are caused. Further, with respect to an inverter circuit as a most fundamental circuit element, generally, in order to improve area efficiency, the gates of the NMOS and the PMOS is laid out such that a connection through metal is avoided, using a piece of polycrystalline silicon which is two-dimensionally continued from the NMOS to the PMOS or a polycide structure composed of a laminate of polycrystalline silicon and high melting metallic silicide. However, when the gate is made of polycrystalline silicon as a single layer, it is impractical due to a high impedance of a PN junction in the polycrystalline silicon. Also, when the gate is made of the polycide structure, an N-type impurity and a P-type impurity each are diffused to respective gate electrodes having an inverse conductivity type through the high melting metallic silicide at high speed during a thermal treatment of steps. As a result, a work function is changed and a threshold voltage is unstable.

### SUMMARY OF THE INVENTION

An object of the present invention is to provide a structure capable of realizing a power management semiconductor device and an analog semiconductor device, in which a low cost, a short manufacturing period, a low voltage operation, and low power consumption are enabled.

In order to solve the above-mentioned object, according to the present invention, the following means are adopted.

(1) There is provided a semiconductor device of a complementary MOS type comprising an N-channel MOS transistor and a P-channel MOS transistor, in which a conductivity type of a gate electrode of the N-channel MOS transistor is a P-type, a conductivity type of a gate electrode of the P-channel MOS transistor is a P-type.

(2) There is provided a semiconductor device of a complementary MOS type in which the P-type gate electrode of the N-channel MOS transistor and the P-type gate electrode of the P-channel MOS transistor are made of first polycrystalline silicon.

(3) There is provided a semiconductor device of a complementary MOS type in which the P-type gate electrode of the N-channel MOS transistor and the P-type gate electrode of the P-channel MOS transistor each have a polycide structure composed of a laminate of first polycrystalline silicon, first high melting metallic silicide, and an insulating film.

(4) There is provided a semiconductor device of a complementary MOS type in which a film thickness of the P-type gate electrode made of the first polycrystalline silicon as a single layer is in a range of from 2000 angstroms to 5000 angstroms.

(5) There is provided a semiconductor device of a complementary MOS type in which in the P-type gate electrode having the polycide structure as a laminate film of the first polycrystalline silicon and the first high melting metallic silicide, a film thickness of the first polycrystalline silicon is in a range of from 2000 angstroms to 4500 angstroms and a film thickness of the first high melting metallic silicide is in a range of from 500 angstroms to 3000 angstroms.

(6) There is provided a semiconductor device of a complementary MOS type in which the first high melting metallic silicide is tungsten silicide, molybdenum silicide, titanium silicide, or platinum silicide.

(7) There is provided a semiconductor device of a complementary MOS type in which the first polycrystalline silicon which composes the P-type gate electrode of the N-channel MOS transistor and the P-type gate electrode of the P-channel MOS transistor include boron or BF₂ at an impurity concentration of 1×10¹⁸ atoms/cm³ or higher.

(8) There is provided a semiconductor device of a complementary MOS type in which the N-channel MOS transistor and the P-channel MOS transistor each include an MOS transistor having a first structure as a single drain structure composed of a high impurity concentration diffusion layer in which a source and a drain are two-dimensionally overlapped with the P-type gate electrode.

(9) There is provided a semiconductor device of a complementary MOS type in which the N-channel MOS transistor and the P-channel MOS transistor each includes a MOS transistor having a second structure comprising: a low impurity concentration diffusion layer having one of structures in which only a drain is two-dimensionally overlapped with the P-type gate electrode and in which both a source and a drain are two-dimensionally overlapped with the P-type gate electrode; and a high impurity concentration diffusion layer having one of structures in which only the drain is not two-dimensionally overlapped with the P-type gate electrode and in which both the source and the drain are not two-dimensionally overlapped with the P-type gate electrode.

(10) There is provided a semiconductor device of a complementary MOS type in which an impurity concentration of the low impurity concentration diffusion layer in the MOS transistor having the second structure is 1×10¹⁶ to 1×10¹⁸ atoms/cm³ and an impurity concentration of the high impurity concentration diffusion layer in the MOS transistor having the first structure and the MOS transistor having the second structure is 1×10¹⁹ atoms/cm³ or higher.

(11) There is provided a semiconductor device of a complementary MOS type in which an impurity of the low impurity concentration diffusion layer in the MOS transistor having the second structure, of the N-channel MOS transistor is one of arsenic and phosphorus and an impurity of the high impurity concentration diffusion layer in the MOS transistor having the first structure and the MOS transistor having the second structure, of the N-channel MOS transistor is one of arsenic and phosphorus.

(12) There is provided a semiconductor device of a complementary MOS type in which an impurity of the low impurity concentration diffusion layer in the MOS transistor having the second structure of the P-channel MOS transistor is one of boron and BF₂, and an impurity of the high impurity concentration diffusion layer in the MOS transistor having the first structure and the MOS transistor having the second structure of the P-channel MOS transistor is one of boron and BF₂.

### BRIEF DESCRIPTION OF THE DRAWINGS

In the accompanying drawings:

FIG. 1 is a cross sectional view of a structure of a semiconductor device of the present invention;

FIG. 2 is a cross sectional view of a structure of a Conventional semiconductor device;

FIG. 3 is a cross sectional view of a structure of a semiconductor device of the present invention; and

FIG. 4 is a diagram for explanation of a voltage regulator circuit of the present invention.

### DETAILED DESCRIPTION OF THE PREFERRED EMBODIMENT

Hereinafter, an embodiment of the present invention will be described based on the drawings. In this embodiment, a case where a complementary type transistor is formed on a P-type semiconductor substrate will be described. However, the present invention can be also applied to a case where it is formed on an N-type semiconductor substrate.

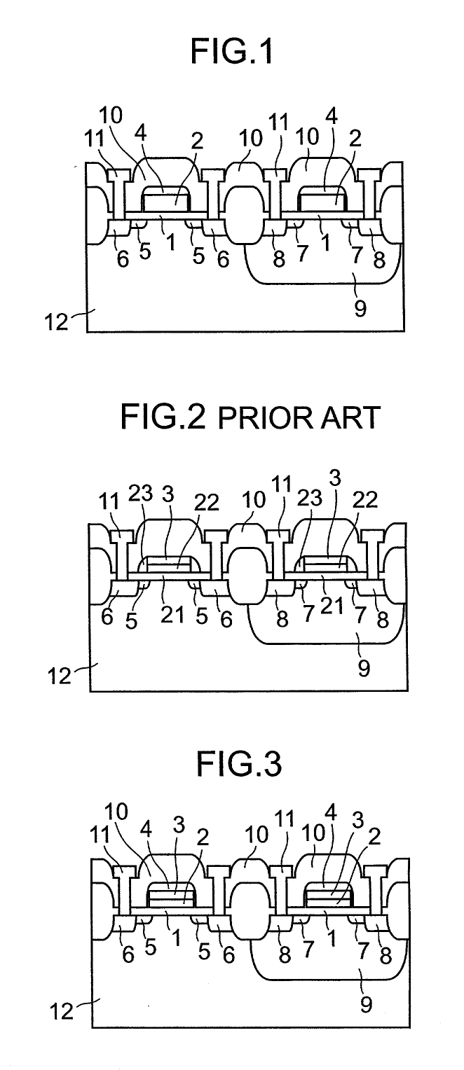

FIG. 1 is a cross sectional view in the case where the present invention is used for a complementary type transistor formed on a semiconductor substrate. An N-type transistor includes a gate insulating film 1 which is nitrided, a P-type polycrystalline silicon gate electrode 2 formed on the gate insulating film 1, N-type impurity regions 5 each having a low concentration N-type impurity introduced in the vicinity of the surface of the semiconductor substrate in a self alignment manner using the P-type polycrystalline silicon gate electrode 2 as a mask, and N-type impurity regions 6 which are spaced from the P-type polycrystalline silicon gate electrode 2 and each have a high concentration N-type impurity introduced in the vicinity of the surface of the semiconductor substrate. Further, a PSG or BPSG interlayer insulating film 10 in which contact holes for electrode formation are provided is formed on the N-type transistor and then metallic electrodes 11 are formed therein. On the other hand, a P-type transistor includes a gate insulating film 1 which is nitrided, a P-type polycrystalline silicon gate electrode 2 formed on the gate insulating film 1, P-type impurity regions 5 each having a low concentration P-type impurity introduced in the vicinity of the surface of the semiconductor substrate in a self alignment manner using the P-type polycrystalline silicon gate electrode 2 as a mask, P-type impurity regions 6 which are spaced from the P-type polycrystalline silicon gate electrode 2 and each have a high concentration P-type impurity introduced in the vicinity of the surface of the semiconductor substrate, and an N-well region 9. Further, the PSG or BPSG interlayer insulating film 10 in which contact holes for electrode formation are provided is formed on the P-type transistor and then metallic electrodes 11 are formed therein.

Here, the thickness of the P-type polycrystalline silicon gate electrode 2 is considered. In the case of the same ion implantation concentration, when the gate electrode is thin, its sheet resistance becomes small and thus it is advantageous. However, boron used for implantation of a P-type ion is easy to pass an oxide film. Therefore, since a boron ion-implanted to the P-type polycrystalline silicon gate electrode 2 passes the gate insulating film 1 and penetrates the channel region of the transistor, this becomes a factor for a variation in a characteristic of the transistor. Thus, there is a method of preventing the penetration of boron to the channel region by reducing the ion implantation concentration. However, according to the present invention, a film thickness of the P-type polycrystalline silicon gate electrode is set to be 2000 angstroms or more so that boron is prevented from passing the P-type polycrystalline silicon gate electrode 2 and penetrating the channel region of the transistor at ion implantation. In the case where it is set to be less than 2000 angstroms, boron passes the P-type polycrystalline silicon gate electrode 2 due to ion implantation energy and penetrates the channel region through the gate insulating film in thermal treatment of later processes to cause a variation in a characteristic. On the other hand, when the P-type polycrystalline silicon gate electrode 2 is thick (2000 angstroms or more), although passing of boron can be prevented, an increase in a sheet resistance is caused. In the case of a circuit for which the transistor of the present invention is used, since a sheet resistance is 1 kÙ/square or lower, a thickness of the P-type polycrystalline silicon gate electrode 2 which is required for satisfying this becomes 5000 angstroms or less. Thus, when a gate electrode is the P-type polycrystalline silicon gate electrode 2 as a single layer, its thickness becomes in a range of from 2000 angstroms to 5000 angstroms.

Further, since the gate insulating film 1 is nitrided, it can be prevented that boron included in the P-type polycrystalline silicon gate electrode passes the gate insulating film 1 to penetrate the channel region of the transistor due to thermal treatment of manufacturing steps. In addition, since an interface level, a trap, a dangling bond of crystal in an interface of the gate insulating film 1 are filled with nitrogen, a hot electron resistance is increased and the reliability of the gate insulating film 1 is improved.

When the gate electrode in the P-type transistor is used as the P-type polycrystalline silicon gate electrode 2, the channel of an enhancement P-type transistor becomes a surface channel from a relationship of work functions between the N-well 9 and the gate electrode. However, in the case of a surface channel P-type transistor, even when a threshold voltage is set to be, for example, −0.5 V or more, extreme deterioration of a subthreshold coefficient is not actualized and both a low voltage operation and a low consumption current are enabled.

On the other hand, in the case of an N-channel transistor, the channel of an enhancement N-type transistor becomes a buried channel from a relationship of work functions between the P-type polycrystalline silicon gate electrode 2 and a P-type semiconductor substrate 12. However, when a threshold value is set to be a desired value, since arsenic having a small diffusion coefficient can be used as a donor impurity for controlling a threshold value, the channel becomes an extremely shallow buried channel. Thus, even when a threshold voltage is set to be, for example, a small value of 0.5 V or lower, as compared with the case of an enhancement P-type transistor in which boron having a large diffusion coefficient and a wide projection range in ion implantation must be used as an acceptor impurity for controlling a threshold value so that the channel becomes a deep buried channel and N-type polycrystalline silicon is used as the gate electrode, deterioration of a subthreshold and an increase in a leak current can be greatly suppressed.

From the above descriptions, it is understood that the CMOS in which the P-type polycrystalline silicon unipole is used as the gate electrode according to the present invention is an effective technique for a low voltage operation and low power consumption, as compared with a conventional CMOS in which an N+-polycrystalline silicon unipole is used as the gate electrode.

Also, a so-called homopolar gate CMOS technique is generally known for a low voltage operation and low power consumption. However, since gate electrodes are separately formed to be a P-type and an N-type in homopolar gate formation, it is necessary to add at least two mask steps as compared with common unipolar gate processes. The reference number of mask steps in the case of a unipolar gate CMOS is about 10 times. However, when the homopolar gate is used, a step cost is increased by 20% at a rough estimate. Thus, from total viewpoints of a performance and a cost of the semiconductor device, the CMOS using the P-type polycrystalline silicon unipole as the gate electrode according to the present invention can be said to be effective.

In the embodiment of the present invention as shown in FIG. 1, a single layer of the P-type polycrystalline silicon is used as the gate electrode. However, in this case, a sheet resistance value of the single layer of the P-type polycrystalline silicon is a large value of about 100 Ù/square. Thus, there is a problem in that an application to a semiconductor device which copes with a high speed operation and high frequency is difficult. For the measures, as shown in FIG. 3, a so-called polycide structure in which the high melting metallic silicide film 3 made of tungsten silicide, molybdenum silicide, titanium silicide, platinum silicide, or the like is formed on the P-type polycrystalline silicon gate electrode 2 is used for the gate electrode to reduce a resistance.

An N-type transistor includes a gate insulating film 1 which is nitrided, a P-type polycrystalline silicon gate electrode 2 formed on the gate insulating film 1, a metallic silicide film 3 formed on the P-type polycrystalline silicon gate electrode 2, an NSG interlayer insulating film 4 formed on the metallic silicide film 3, N-type impurity regions 5 each having a low concentration N-type impurity introduced in the vicinity of the surface of the semiconductor substrate in a self alignment manner using the P-type polycrystalline silicon gate electrode 2, the metallic silicide film 3, and the NSG interlayer insulating film 4 as masks, and N-type impurity regions 6 which are spaced from the P-type polycrystalline silicon gate electrode 2 and each have a high concentration N-type impurity introduced in the vicinity of the surface of the semiconductor substrate. Further, a PSG or BPSG interlayer insulating film 10 in which contact holes for electrode formation are provided is formed on the N-type transistor and then metallic electrodes 11 are formed therein. On the other hand, a P- type transistor includes a gate insulating film 1 which is nitrided, a P-type polycrystalline silicon gate electrode 2 formed on the gate insulating film 1, a metallic silicide film 3 formed on the P-type polycrystalline silicon gate electrode 2, an NSG interlayer insulating film 4 formed on the metallic silicide film 3, P-type impurity regions 5 each having a low concentration P-type impurity introduced in the vicinity of the surface of the semiconductor substrate in a self alignment manner using the P-type polycrystalline silicon gate electrode 2, the metallic silicide film 3, and the NSG interlayer insulating film 4 as masks, P-type impurity regions 6 which are spaced from the P-type polycrystalline silicon gate electrode 2 and each have a high concentration P-type impurity introduced in the vicinity of the surface of the semiconductor substrate, and an N-well region 9. Further, the PSG or BPSG interlayer insulating film 10 in which contact holes for electrode formation are provided is formed on the P-type transistor and then metallic electrodes 11 are formed therein.

A sheet resistance value is dependent on a kind and a thickness of the high melting metallic silicide film 3. Normally, in the case of a film thickness in a range of from 500 angstroms to 250 angstroms, the sheet resistance value is over ten Ù/square to several Ù/square. The operations of the MOSs are determined by work functions between the P-type polycrystalline silicon and the semiconductor. Thus, with respect to low voltage operation, low power consumption, and a low cost, the same effect as one described in FIG. 1 is obtained. Also, since the resistance of the gate electrode is reduced, the performance of the semiconductor device is further improved by the reduction.

Here, the film thickness of the metallic silicide film 3 is considered. Since a sheet resistance for coping with a high speed operation and high frequency is over ten Ù/square or lower, the film thickness of the metallic silicide film which is required for satisfying this becomes 500 angstroms or more. Also, the sheet resistance is reduced with increasing the film thickness of the metallic silicide film 3. However, since the metallic silicide film 3 is formed on the P-type polycrystalline silicon gate electrode 2 in processes, a step becomes large. A range (thickness) such as the step is allowed in processes is 5000 angstroms obtained by adding the thickness of the polycrystalline silicon gate electrode to that of the metallic silicide film. Thus, the film thickness of the polycrystalline silicon gate electrode 2 is 4500 angstroms or less. Further, in order to prevent passing of boron which is concerned at ion implantation for forming the P-type polycrystalline silicon gate electrode 2, the thickness of the polycrystalline silicon gate electrode 2 is set to be 2000 angstroms or more. From the above conditions, in the case of the gate electrode using the metallic silicide film 3, the film thickness of the polycrystalline silicon gate electrode is within a range of 2000 angstroms to 4500 angstroms and the film thickness of the metallic silicide film 3 becomes within a range of 500 angstroms to 3000 angstroms.

According to the embodiment of the present invention, in a semiconductor integrated circuit device in which the P-type transistor is used in relatively many cases as compared with the N-type transistor, the P-type transistor is composed of a surface channel type transistor such that a channel length is easily reduced for a short channel. Thus, improvement of the drive capacity and miniaturization thereof are promoted.

Also, when a buried channel which is not suitable for a short channel is applied to the N-type transistor, it is a disadvantage for only the N-type transistor. However, when the comparison with the performance of a conventional buried channel P-type transistor is made, the drive capacity can be greatly improved as compared with a conventional case. This is because, even if the N-type transistor and the P-type transistor supposedly have an identical channel length, an electron as a carrier of the N-type transistor has a larger mobility than a hole as a carrier of the P-type transistor.

Also, when a minimum channel length of the N-type transistor is determined, there is the case where such a length is not necessarily determined by a short channel effect. This is the case where bipolar operation (snap-back phenomenon) due to a substrate current of the N-type transistor is caused. This is because a drain current and a drain electric field are increased with a short channel and generation of a hot carrier is promoted. On the other hand, since the number of generations of hot carriers in the P-type transistor is extremely smaller than in the N-type, there is almost no case where the channel length is determined by the snap-back phenomenon. In other words, in the case of an application such as the present invention, it is opposite to common sense with respect to miniaturization and a short channel is easy to obtain in the P-type transistor rather than the N-type transistor. Also from such a viewpoint, it is very effective that the P-type transistor of the present invention is composed of a surface channel type and the N-type transistor thereof is composed of a buried channel type.

Further, the number of generations of hot carriers in the N-type transistor is smaller in the buried channel type rather than the surface channel type. Here, hot carrier generation regions of the surface channel type transistor and the buried channel type transistor. The hot carrier generation region in the surface channel is produced near the gate oxide film. On the other hand, the hot carrier generation region in the buried channel is produced in a region deeper than the gate oxide film. Thus, a hot carrier is trapped and a distance between the gate oxide film and the channel region, by which deterioration of a transistor characteristic is caused, is increased to reduce the deterioration of the transistor characteristic.

Also, when a limitation of a short channel of the N-type transistor is not determined by a leak current, this becomes a factor capable of breaking through the limitation of the short channel due to the snap-back phenomenon. In other words, in this case, the short channel of the N-type transistor can be also promoted.

Further, in the present invention, when an N-type impurity is implanted using the P-type polycrystalline silicon gate electrode 2 as a mask, an increase in a resistance and depletion of the gate electrode due to a reduction in a concentration of the P-type polycrystalline silicon gate electrode 2 are concerned. In order to solve such a problem, the insulating film 4 is formed on the P-type polycrystalline silicon gate electrode 2. Alternatively, the metallic silicide film 3 is formed on the P-type polycrystalline silicon gate electrode 2 and the insulating film 4 is formed thereon. Thus, when an N-type impurity is implanted using the P-type polycrystalline silicon gate electrode 2 as a mask, it is possible that the implantation of the N-type impurity into the P-type polycrystalline silicon gate electrode 2 is prevented.

Further, when a structure of the source and drain regions of the transistor is viewed, each of these is composed of a low impurity concentration region and a high impurity concentration region. An LDD structure is also the same structure as this. However, in the case of the LDD structure, the width of the low impurity concentration region is determined by the thickness of a spacer. On the other hand, according to the semiconductor device of the present invention, an interval between the high impurity concentration region and the polycrystalline silicon gate electrode 2 can be arbitrarily set. Thus, in the case of a drain apply voltage of 7 V, the interval is set to be about 0.5 to 1.0 μm. In the case of 10 V, it is set to be about 0.7 to 2.0 μm. In the case of 36 V, it is set to be about 2.0 to 5.0 μm.

Here, concentrations of the low impurity concentration region and the high impurity concentration region are considered. Since the sheet resistance of the polycrystalline silicon gate electrode 2 is limited to be 1 kÙ/square or lower, a concentration of the high impurity concentration region becomes 1×10¹⁹ atoms/cm³ or higher. Since a drain apply voltage of the transistor used in the present invention is assumed to be several V to 40 V, a concentration of the low impurity concentration region is within a range of 1×10¹⁶ to 1×10¹⁸ atoms/cm³.

In the structures shown in FIGS. 1 and 3, low concentration P-type impurity regions 7 include boron or BF₂ in a concentration of about 1×10¹⁶ to 1×10¹⁸ atoms/cm³ and the low concentration N-type impurity regions 5 include phosphorus or arsenic in a concentration of about 1×10¹⁶ to 1×10¹⁸ atoms/cm³. On the other hand, high concentration P-type impurity regions 8 include boron or BF₂ in a concentration of 1×10¹⁹ atoms/cm³ or higher and the high concentration N-type impurity regions 6 include phosphorus or arsenic in a concentration of 1×10¹⁹ atoms/cm³ or higher.

In the case of the transistor thus obtained, which constitutes the complementary transistor device, since the P-type polycrystalline silicon is used for the gate electrode, the channel of the P-type transistor is produced as the surface channel and the channel of the N-type transistor is produced as the buried channel. The surface channel P-type transistor has stability of its transistor characteristic, reliability, and performance, which are superior to the conventional buried channel P-type transistor. In particular, when the channel is shortened, a leak current between the source and the drain can be greatly decreased and miniaturization is made easily.

According to the present invention, the silicon system semiconductor device is mainly described. However, the present invention can be also applied to a semiconductor device using another material such as germanium, silicon carbide, or gallium arsenide. Further, in the present invention, for example, a reduction in a resistance of the gate electrode serves an important role. In addition to the silicon gate mainly described in the present invention, a material capable of producing a surface channel in the P-type transistor may be used for the gate electrode. Steps of manufacturing the transistors on the P-type semiconductor substrate are described in this embodiment. However, the present invention can be also applied to the case where a thin film transistor (TFT) is manufactured using a polycrystalline or a single crystalline semiconductor coating film which is formed on an insulating substrate made of quartz, sapphire, or the like.

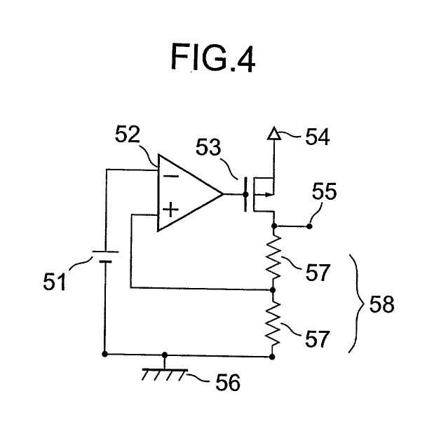

Next, a specific effect in the case where the present invention is applied to the actual product will be described using FIG. 4.

FIG. 4 shows schematically a structure of a positive type voltage regulator using a semiconductor device. The voltage regulator includes a reference voltage circuit 51, an error amplifier 52, a PMOS output element 53, and a voltage dividing circuit 58 composed of resistors 57. This regulator is a semiconductor device having a function such as a constant voltage is always outputted to an output terminal 55 together with a necessary current value even if an arbitrary voltage is inputted to an input terminal 54.

In recent years, a reduction in an input voltage, low power consumption, an output of a large amount of current by a small potential difference between input and output, high precision of an output voltage, a low cost, miniaturization, and the like are required from the market to particularly a voltage regulator for a portable device. In particular, a low cost and miniaturization are requirements with high priority. For the above requirements, the structure of the present invention is used. That is, the error amplifier, the PMOS output element, and the reference voltage circuit each are composed of a CMOS in which a low cost and a low threshold voltage are possible. In addition, the voltage dividing circuit is composed of a P-resistor having a low cost, a high resistance, and high precision. Thus, supports for low voltage operation, low power consumption, and high precision of an output voltage are possible. Further, for a low cost which is a requirement with highest priority, that is, for a reduction in a chip size and miniaturization, the structure of the present invention produces an extremely large effect. Its specific example will be described.

The voltage regulator (VR) outputs a current of several tens of mA to several hundreds of mA. However, this is dependent on drive capacity of a P-type transistor output element at 100% and there is the case where the P-type transistor output element occupies about a half of a chip area according to a product. Thus, it is a key to a low cost and miniaturization that the size of the P-type transistor output element is minimized.

On the other hand, as described above, market requirements for a reduction in an input voltage and an output of a large amount of current by a small potential difference between input and output are strong. This indicates that a large amount of current is produced in a non-saturation operation mode such as a voltage applied to the gate is small and a voltage between the source and the drain is small in the P-type transistor output element. A drain current of an MOS transistor in the non-saturation operation is indicated by the following equation:

Id=(μ·Cox·W/L)×{(Vgs−vth)−½·Vds }×vds (1)

where Id: a drain current,

μ: mobility

Cox: a capacitance of the gate insulating film

W: a channel width

L: a channel length

Vgs: a voltage between the gate and the source

Vth: a threshold voltage, and

Vds: a voltage between the drain and the source.

When an area is not increased and a sufficiently large drain current is obtained even in the case where Vgs and Vds are small, shortening of the channel and a reduction in Vth are required to be realized from the equation (1).

In the case of the CMOS structure using the P-type polycrystalline silicon gate electrode 2 as the gate according to the present invention, a reduction in the threshold voltage and shortening of the channel can be made with suppressing a leak current at an off state. Thus, this can be understood to be very effective means for a low cost and miniaturization of the above VR. Of course, even when the homopolar gate CMOS technique is used, the same effect is obtained with respect to the chip size. However, in terms of cost, since the number of steps is increased, the same effect as the present invention is not totally obtained.

Also, an advantage of the CMOS structure using the P-type polycrystalline silicon gate electrode according to the present invention in the VR is as follows. That is, when the reference voltage circuit is composed of an enhancement N-type transistor and a depletion N-type transistor (hereinafter referred to as a D-type NMOS), since both the E-type NMOS and the D-type NMOS are buried channel types, threshold voltages in respective transistors and a change in a transconductance with respect to a change in a temperature can be made to be the same degree. Also, as compared with a reference voltage circuit which is composed of the E-type NMOS of the surface channel type and the D-type NMOS of the buried channel type in the conventional case where the N-type polycrystalline silicon is used for the gate electrode, a reference voltage circuit in which a change in an output voltage with respect to a change in a temperature is small can be also provided.

Further, according to the conventional N-type polycrystalline silicon gate structure, in particular, since a variation in a threshold voltage in the depletion type is large, an enhancement/depletion type reference voltage circuit of P-type transistor cannot be actually used. However, according to the CMOS structure using the P-type polycrystalline silicon gate electrode according to the present invention, the enhancement/depletion type reference voltage circuit of P-type transistor can be actually used. Thus, since the N-type transistor or the P-type transistor can be selected in the enhancement/depletion type reference voltage circuit, the present invention also has an advantage such that a degree of freedom in a circuit design is increased.

The effect of the present invention in the voltage regulator is described above. Note that, when the present invention is applied to the case of a switching regulator in which a high output element is mounted and the case of a voltage detector in which requirements such as low voltage operation, low power consumption, a low cost, and miniaturization are strong, many effects can be obtained as in the case of the voltage regulator.

According to the embodiment of the present invention, the following effects can be obtained by using the above-mentioned structure.

(1) When the structure such that the gate electrode of the N-type transistor is the P-type polycrystalline silicon gate electrode and the gate electrode of the P-type transistor is the P-type polycrystalline silicon gate electrode is used, the N-type transistor becomes the buried channel type transistor and the P-type transistor becomes the surface channel type transistor. Thus, when the channel length is determined by the snap-back phenomenon, a short channel is easy to obtain in the P-type transistor rather than the N-type transistor. Particularly in a semiconductor integrated circuit device for the voltage regulator, since a ratio of an area occupied by the P-type transistor is very large, effects of high speed drive and miniaturization due to a short channel of the P-type transistor are large and a cost reduction effect is also remarkable. Further, the hot carrier generation region in the surface channel is produced near the gate oxide film. However, the hot carrier generation region in the buried channel is produced in a region deeper than the gate oxide film. Thus, an effect can be obtained such that a hot carrier is trapped and a distance between the gate oxide film and the channel region, by which deterioration of a transistor characteristic is caused, is increased to reduce the deterioration of the transistor characteristic.

(2) When the gate insulating film is nitrided, an interface level, a trap, a dangling bond of crystal in an interface of the gate insulating film 1 are filled with nitrogen, a hot electron resistance is increased and the reliability of the gate insulating film 1 is improved. Further, it can be prevented that boron included in the P-type polycrystalline silicon gate electrode passes the gate insulating film 1 to penetrate the channel region of the transistor due to thermal treatment of manufacturing steps.

(3) With respect to a structure of the source and drain regions of the transistor, each of these is composed of a low impurity concentration region and a high impurity concentration region. Further, an interval between the impurity regions having a high impurity concentration and the polycrystalline silicon gate electrode can be arbitrarily set. Thus, when a drain apply voltage is changed according to an application, there is provided an effect that it can be coped with by changing the interval between the impurity regions having a high impurity concentration and the polycrystalline silicon gate electrode without changing manufacturing step conditions.

(4) The insulating film is formed on the P-type polycrystalline silicon gate electrode or the metallic silicide film. Thus, when an N-type impurity is implanted using the P-type polycrystalline silicon gate electrode as a mask, it is possible that the implantation of the N-type impurity into the P-type polycrystalline silicon gate electrode is prevented. Therefore, there can be obtained an effect that an increase in a resistance and depletion of the gate electrode due to a reduction in a concentration of the P-type polycrystalline silicon gate electrode are prevented.

What is claimed is:

1. A semiconductor device of a complementary MOS type comprising an N-channel MOS transistor and a P-channel MOS transistor, wherein:
a conductivity type of a gate electrode of the N-channel MOS transistor is a P-type; a conductivity type of a gate electrode of the P-channel MOS transistor is a P-type; and gate insulating films of the N-channel MOS transistor and the P-channel MOS transistor are nitrided.

2. A semiconductor device of a complementary MOS type according to claim 1, wherein the P-type gate electrode of the N-channel MOS transistor and the P-type gate electrode of the P-channel MOS transistor are made of first polycrystalline silicon.

3. A semiconductor device of a complementary MOS type according to claim 1, wherein the P-type gate electrode of the N-channel MOS transistor and the P-type gate electrode of the P-channel MOS transistor each have a polycide structure composed of a laminate film of first polycrystalline silicon, first high melting metallic silicide, and an insulating film.

4. A semiconductor device of a complementary MOS type according to claim 1, wherein the N-channel MOS transistor and the P-channel MOS transistor each includes a MOS transistor having a second structure comprising: a low impurity concentration diffusion layer having one of structures in which only a drain is two-dimensionally overlapped with the P-type gate electrode and in which both a source and a drain are two-dimensionally overlapped with the P-type gate electrode; and a high impurity concentration diffusion layer having one of structures in which only the drain is not two-dimensionally overlapped with the P-type. gate electrode and in which both the source and the drain are two-dimensionally overlapped with the P-type gate electrode.

5. A semiconductor device of a complementary MOS type according to claim 1, wherein a film thickness of the P-type gate electrode made of the first polycrystalline silicon as a single layer is in a range of from 2000 angstroms to 5000 angstroms.

6. A semiconductor device of a complementary MOS type according to claim 1, wherein in the P-type gate electrode having the polycide structure as a laminate of the first polycrystalline silicon and the first high melting metallic silicide, a film thickness of the first polycrystalline silicon is in a range of from 2000 angstroms to 4500 angstroms and a film thickness of the first high melting metallic silicide is in a range of from 500 angstroms to 3000 angstroms.

7. A semiconductor device of a complementary MOS type according to claim 1, wherein an impurity concentration of the low impurity concentration diffusion layer in the MOS transistor having the second structure is 1×10¹⁶ to 1×10¹⁸ atoms/cm³, and an impurity concentration of the high impurity concentration diffusion layer in the MOS transistor having the first structure and the MOS transistor having the second structure is 1×10¹⁹ atoms/cm³ or higher.

8. A semiconductor device of a complementary MOS type according to claim 1, wherein an impurity of the low impurity concentration diffusion layer in the MOS transistor having the second structure of the N-channel MOS transistor is one of arsenic and phosphorus and an impurity of the high impurity concentration diffusion layer in the MOS transistor having the first structure, and the MOS transistor having the second structure of the N-channel MOS transistor is one of arsenic and phosphorus.

9. A semiconductor device of a complementary MOS type according to claim 1, wherein an impurity of the low impurity concentration diffusion layer in the MOS transistor having the second structure of the P-channel MOS transistor is one of boron and BF₂ and an impurity of the high impurity concentration diffusion layer in the MOS transistor having the first structure, and the MOS transistor having the second structure of the P-channel MOS transistor is one of boron and BF₂.
